(19) United States
(12) Patent Application Publication
(10) Pub. No.: US 2015/0048510 A1
(43) Pub. Date: Feb. 19, 2015

(54) SEMICONDUCTOR DEVICE

(71) Applicant: DENSO CORPORATION, Kariya-city, Aichi-pref. (JP)

(72) Inventors: Manabu Tomisaka, Nagoya-city (JP); Yoshifumi Okabe, Anjo-city (JP); Mikimasa Suzuki, Toyohashi-city (JP)

(21) Appl. No.: 14/383,915

(22) PCT Filed: Apr. 22, 2013
(86) PCT No.: PCT/JP2013/002685

§ 371 Date: Sep. 9, 2014

(30) Foreign Application Priority Data
Apr. 23, 2012 (JP) 2012-97718
Feb. 11, 2013 (JP) 2013-23936

(51) Int. Cl. H01L 23/00; H01L 21/288; H01L 21/02

(52) U.S. Cl. CPC H01L 24/05; H01L 24/03; H01L 21/02521; H01L 21/288; H01L 2224/03332; H01L 2224/03462; H01L 2224/03442; H01L 2224/0345; H01L 2224/03848; H01L 2224/03505; H01L 2224/0401; H01L 2224/05155; H01L 2224/05647; H01L 2224/05624; H01L 2224/05666; H01L 2224/05023; H01L 2924/01021; H01L 2924/01023; H01L 2924/01024; H01L 2924/01026; H01L 2924/01027; H01L 2924/0104; H01L 2924/01041; H01L 2924/01042; H01L 2924/01072; H01L 2924/01073; H01L 2924/01005; H01L 2924/01015; H01L 2924/0132; H01L 2924/01074; H01L 2924/0105; H01L 2924/014
USPC 257/762; 257/763; 257/766; 204/192.25; 438/678

(57) ABSTRACT

A semiconductor device includes a semiconductor substrate and a metal film formed on the semiconductor substrate. The metal film includes a Ni base and a material having condensation energy higher than that of Ni. In a method of manufacturing a semiconductor device, a semiconductor substrate and a target, which is formed by melting P in Ni, are prepared, and sputtering is performed with the target while a portion of the semiconductor substrate where the metal film is to be formed is heated to a temperature of from 280° C. inclusive to 870° C. inclusive.

### CROSS REFERENCE TO RELATED APPLICATION

This application is based on Japanese Patent Application No. 2012-97718 filed on Apr. 23, 2012 and Japanese Patent Application No. 2013-23936 filed on Feb. 11, 2013, the contents of which are incorporated herein by reference.

### TECHNICAL FIELD

The present invention relates to a semiconductor device where a metal film is formed on a semiconductor substrate.

### BACKGROUND ART

As described in, for example, a patent document 1, a structure of a semiconductor substrate with an electrode portion has been proposed. In the patent document 1, a post as a metal film is on the electrode portion. For example, the post is made of Ni—P based alloy.

### PRIOR ART

### Patent Document

Patent Document 1: JP-A-2005-209861

### SUMMARY OF THE INVENTION

In the structure disclosed in the patent document 1, if a bump such as Sn is formed on the post, the post is partially eroded by the bump at the time of forming the bump. Accordingly, since the thickness of the post becomes smaller than its initial thickness, reliability of connection between the post and the bump becomes a matter of concern. Although P contained in the post has an effect on delaying allowing between Ni of the post and Sn of the bump, the post needs to have a large initial thickness to ensure the reliability of connection between the post and the bump. Therefore, it is difficult to allow the post to have a small initial thickness while ensuring the reliability of connection between the post and the bump.

In view of the above, it is a first object of the present disclosure to provide a semiconductor device having a metal film capable of having a small initial thickness while ensuring connection reliability. It is a second object of the present disclosure to provide a method of manufacturing a semiconductor device having such a structure.

According to a first aspect of the present disclosure, a semiconductor substrate and a metal film formed on the semiconductor substrate are included, and the metal film includes a Ni base and a material having condensation energy higher than that of Ni.

Thus, bond strength between Ni and the material having higher condensation energy is improved, so that film density of the metal film can be improved. Therefore, since diffusion of a joint material into the metal film occurring when the joint material is joined to the metal film is reduced, reliability of junction between the metal film and the joint material is ensured without a reduction in an initial thickness of the metal film. Therefore, the initial thickness of the metal film can be reduced while the junction reliability of the metal film is ensured.

According to a second aspect of the present disclosure, the material having condensation energy higher than that of Ni can be any of Sc, Ti, V, Cr, Fe, Co, Zr, Nb, Mo, Hf, Ta, W, B, and P.

According to a third aspect of the present disclosure, the material having condensation energy higher than that of Ni can be a stoichiometric material represented by NiₓP_{y}, where each of x and y is an integer. For example, the material having condensation energy higher than that of Ni can be a Ni₃P particle.

Thus, in Ni₃P, since Ni—Ni bond and Ni—P bond are strengthened compared to when P is simply mixed in Ni, the condensation energy is increased. Accordingly, the film density of the metal film containing Ni₃P particle is increased.

According to a fourth aspect of the present disclosure, the Ni₃P particle is uniformly distributed in the Ni base. Thus, a reduction in mechanical strength of the Ni₃P particle is prevented.

According to a fifth aspect of the present disclosure, a semiconductor substrate and a target which is formed by melting P in Ni are prepared. Then, a metal film having a Ni base containing a Ni₃P particle is formed on the semiconductor substrate by sputtering with the target while a portion of the semiconductor substrate where the metal film is to be formed to a temperature of from 280° C. inclusive to 870° C. inclusive.

According to a sixth aspect of the present disclosure, a semiconductor substrate and a target which is formed by sintering Ni powder and Ni₃P powder are prepared, and a metal film having a Ni base containing a Ni₃P particle is formed on the semiconductor substrate by sputtering with the target.

According to a seventh aspect of the present disclosure, a semiconductor substrate and a plating solution containing Ni and P are prepared, the semiconductor substrate is soaked in the plating solution, and then a metal film having a Ni base containing a Ni₃P particle is formed on the semiconductor substrate by heating the semiconductor substrate.

A metal film having a Ni base containing a Ni₃P particle can be formed by any one of the fifth to seventh aspects of the present disclosure.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a cross-sectional view of a semiconductor device according to a first embodiment of the present disclosure;

FIG. 2A is a diagram illustrating Ni atoms bound together, and FIG. 2B is a diagram showing a Ni₃P molecule binding;

FIG. 3 is a diagram showing a comparison in condensation energy between Ni and Ni₃P;

FIG. 4 is a diagram showing a comparison in bond order between Ni—Ni and Ni—P;

FIG. 5 is a cross-sectional view of a semiconductor device having a bump formed on a metal film;

FIG. 6 is a diagram showing a comparison in thickness between a conventional metal film and a metal film according to the present disclosure;

FIG. 7 is a diagram showing a comparison in the amount of thickness of a metal film between before and after a reflow;

FIG. 8 is a diagram illustrating an example of a result of a x-ray diffraction of a metal film containing Ni₃P;

FIG. 9 is a diagram illustrating a relationship between a Ni₃P/Ni ratio and a reflow thickness reduction;

FIG. 10 is a diagram illustrating a TEM image of a metal film according to a third embodiment;

FIG. 11 is a cross-sectional view of a semiconductor device according to a fourth embodiment of the present disclosure;

FIG. 12 is a cross-sectional view of a semiconductor device according to a fifth embodiment of the present disclosure;

FIG. 13 is a cross-sectional view of a semiconductor device according to a sixth embodiment of the present disclosure;

FIGS. 14A, 14B, 14C, and 14D are diagrams illustrating an example of a method of manufacturing a semiconductor device according to a seventh embodiment;

FIG. 15 is a diagram showing a comparison in cutting resistance between various films in the seventh embodiment;

FIG. 16 is a diagram showing a relationship between a Ni₃P/Ni ratio and a tensile strength according to an eighth embodiment; and

FIG. 17 is a diagram showing a comparison in condensation energy between Ni and other materials.

### EMBODIMENTS OF THE INVENTION

Embodiments of the present disclosure are described below with reference to the drawings in which like characters of reference indicate the same or equivalent parts.

### First Embodiment

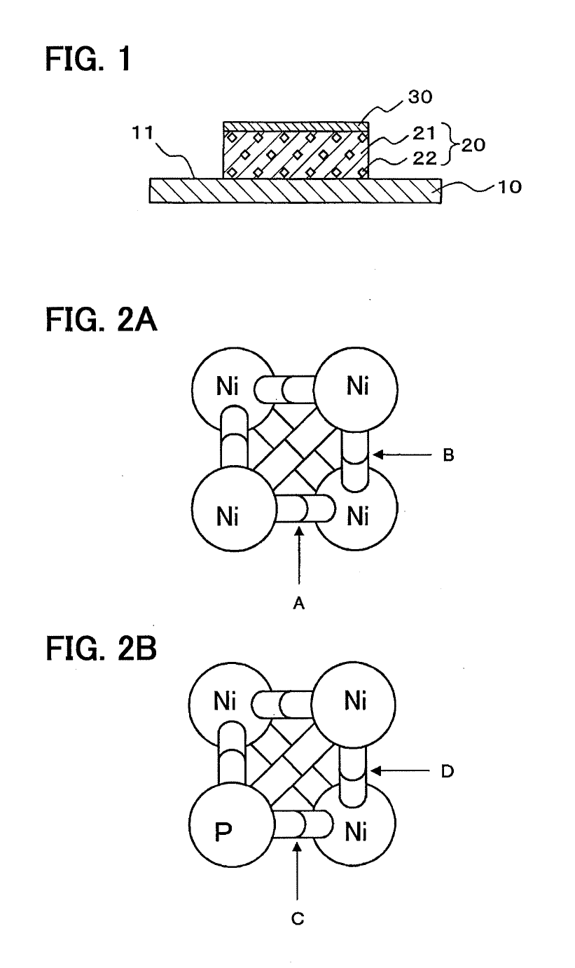

A first embodiment of the present disclosure is described below with reference to the drawings. As shown in FIG. 1, a semiconductor device includes a semiconductor substrate 10, a metal film 20, and an Au thin-film 30.

For example, the semiconductor substrate 10 is a substrate where a semiconductor element, such as a MOSFET, an IGBT, a diode, etc., is formed. For example, the semiconductor substrate 10 is a Si substrate or the like. For example, a thickness of the semiconductor substrate 10 is several hundreds of micrometers.

The metal film 20 is a thin film formed on the semiconductor substrate 10. According to the present embodiment, the metal film 20 is formed on a surface 11 of the semiconductor substrate 10. The metal film 20 includes a Ni base 21 and Ni₃P particles 22.

The Au thin-film 30 is formed on the metal film 20. The Au thin-film 30 allows a junction member such as a bump formed on the metal film 20 to be wetted easily.

As shown in FIG. 2A, the Ni base 21 is made of Ni atoms bound together. That is, the Ni base 21 is a metal body made of Ni atoms bound together. In contrast, as shown in FIG. 2B, a Ni₃P molecule contains one P atom and three Ni atoms that are bound together.

A lot of the Ni₃P particles 22 are distributed in the Ni base 21. The Ni₃P particles 22 are uniformly distributed in the Ni base 21. If the Ni₃P particles 22 are bound together, mechanical strength is reduced. For this reason, it is preferable that the Ni₃P particles 22 be uniformly distributed in the Ni base 21.

Next, a method of manufacturing the semiconductor device shown in FIG. 1 is described. According to the present embodiment, the metal film 20 is formed on the metal film 20 by sputtering using a target.

Firstly, a preparing process is performed. Specifically, a semiconductor substrate 10 where a metal film 20 is to be formed is prepared. Typically, the semiconductor substrate 10 is in the form of a semiconductor wafer. Further, a target used in sputtering is prepared. The target is formed by melting P in Ni.

Next, a sputtering process is performed. In this process, sputtering is performed using the target while maintaining a surface temperature of the semiconductor wafer in a range of from 280° C. inclusive to 870° C. inclusive by application of heat. That is, sputtering is performed using the target while heating a portion of the semiconductor substrate 10 where the metal film 20 is to be formed to a temperature of from 280° C. inclusive to 870° C. inclusive.

It is noted that the temperature “280° C.” is a temperature at which Ni₃P is generated. The temperature 870° C. is a melting temperature of Ni₃P. Therefore, when sputtering is performed under a temperature in a range of from 280° C. inclusive to 870° C. inclusive, the metal film 20 having the Ni base 21 containing the Ni₃P particles is formed on the semiconductor substrate 10.

The semiconductor device having the metal film 20 is completed by dicing the semiconductor wafer into individual semiconductor substrates 10 after forming the metal film 20. Alternatively, sputtering can be performed in the form of the semiconductor substrate instead of the semiconductor wafer.

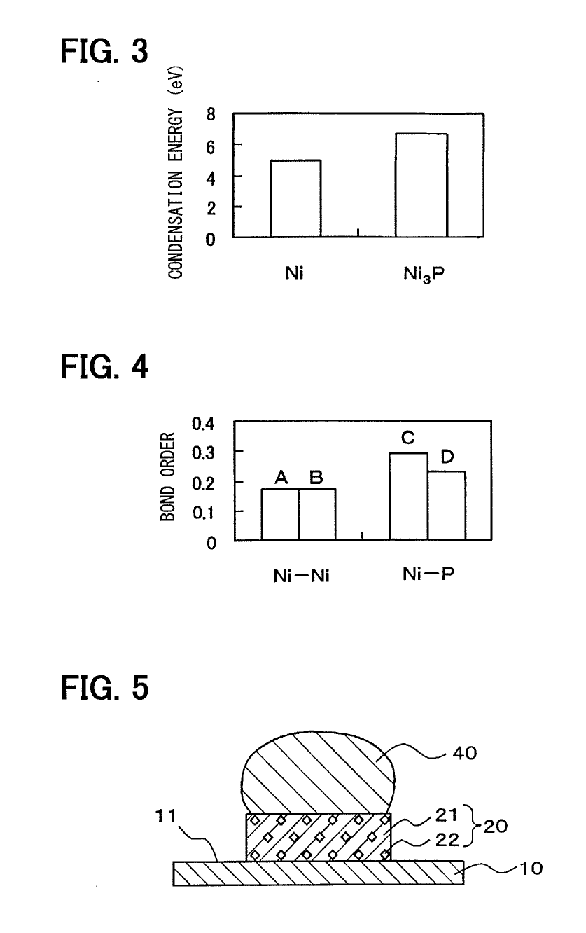

The inventors examined the effects of adding Ni to P. FIGS. 3 and 4 show results of first-principles calculation.

As shown in FIG. 3, regarding condensation energy as an Indicator of stability of a metal, condensation energy of a Ni₃P molecule is higher than that of Ni atoms. High condensation energy results in high film density of the metal film 20. This indicates that bond strength is larger than when Ni and P bind together in Ni₃P than when Ni atoms bind together and that stability increases as an alloy. As an alloy is more stable, diffusion of heterogeneous elements such as Sn can be further reduced.

FIG. 4 shows bond orders at binding sites A-D shown in FIGS. 2A and 2B. In the Ni—Ni bond shown in FIG. 2A, each of the bond orders at the sites A and B is about 0.2. In contrast, in the N—P bond shown in FIG. 2B, the bond order at the site C is about 0.3, and the bond order at the site D is about 0.25. That is, bond strength is larger in the Ni—P bond C than in the Ni—Ni bond A. Further, because of P, bond strength is larger in the Ni—P bond D than in the Ni—Ni bond B.

The results of FIG. 3 and FIG. 4 indicate that when a bump to be formed on the metal film 20 contains Sn, the initial thickness of the metal film 20 can be reduced. As shown in FIG. 5, the metal film 20 is to be joined to a solder member 40 containing Sn. When the solder member 40 is joined on the metal film 20, alloying of Sn and Si occurs. Therefore, the thickness of the metal film 20 is reduced by the amount corresponding to the alloying. However, since the bond strength of each of Ni—Ni bond and Ni—P bond is large due to the fact that the Ni base 21 contains the Ni₃P particles 22, the alloying of Ni of the metal film 20 and Sn of the solder member 40 can be slowed down. By such an action of Ni₃P, the thickness of the metal film 20 can be reduced than before. It is noted that the Au thin-film 30 on the metal film 20 is absorbed by the solder member 40.

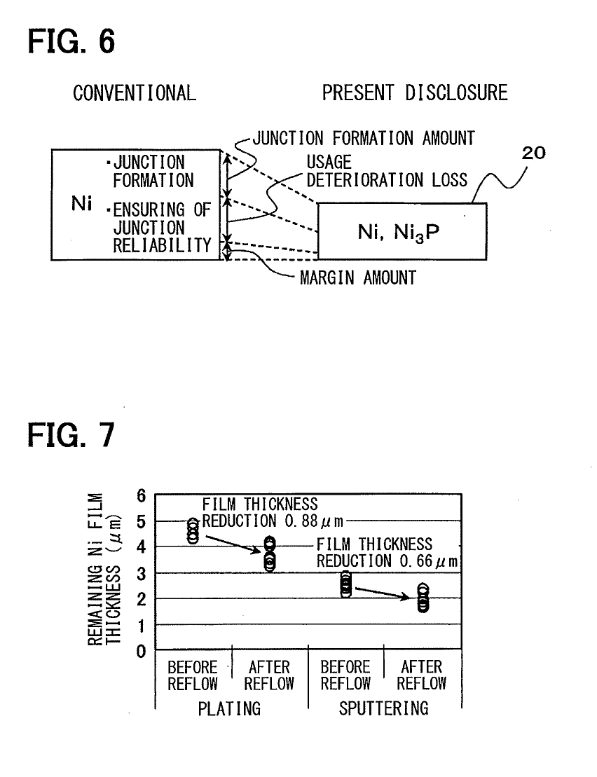

Specifically, as shown in FIG. 6, a thickness of a conventional metal film is designed in consideration of the amounts of junction formation, usage deterioration loss, and a margin so that a junction can be formed and junction reliability can be ensured. For this reason, the thickness of the conventional metal film is about 5 μm or more.

In contrast, since the metal film 20 is formed by distributing the Ni₃P particles 22 in the Ni base 21, the allowing of a portion of the metal film 20 and the solder member 40 can be slowed down. Therefore, as shown in FIG. 6, even when all the thicknesses corresponding to the amounts of the junction formation, the usage deterioration loss, and the margin are smaller than those of the conventional metal film, the same reliability as the conventional metal film can be ensured. Therefore, the thickness of the metal film 20 according to the present disclosure can be about 3 μm or less. Thus, the initial thickness can be smaller than that of the conventional metal film while the same reliability as the conventional metal film is ensured.

The present inventors evaluated the amount of reduction in the thickness of each of the conventional metal film and the metal film 20 of the present disclosure when the solder member 40 is joined to them in multiple samples. FIG. 7 shows the result. In FIG. 7, “remaining Ni thickness” represents the thickness of the metal film 20.

In FIG. 7, the conventional metal film is formed by plating, and the metal film 20 of the present disclosure is formed by sputtering. Further, “before reflow” represents the thickness of the metal film 20 before the solder member 40 is joined, and “after reflow” represents the thickness of the metal film 20 after the solder member 40 is joined.

According to the result shown in FIG. 7, the thickness of the conventional metal film is reduced by 0.88 μm before and after reflow. In contrast, the thickness of the metal film 20 of the present disclosure is reduced by 0.66 μm before and after reflow. This shows that the amount of reduction in the thickness of the metal film 20 is smaller than that of the conventional metal film by the action of the Ni₃P particles 22 contained in the metal film 20. That is, a diffusion of a component (Sn) of the solder member 40 into the metal film 20 is reduced.

Further, the present inventors performed a X-ray diffraction measurement of the metal film 20 to determine an optimum value of a ratio of the Ni base 21 to the Ni₃P particles 22, i.e., a X-ray diffraction strength ratio Ni₃P/Ni. The X-ray diffraction strength ratio is a ratio of a X-ray diffraction strength of the Ni base 21 to a X-ray diffraction strength of the Ni₃P particles 22.

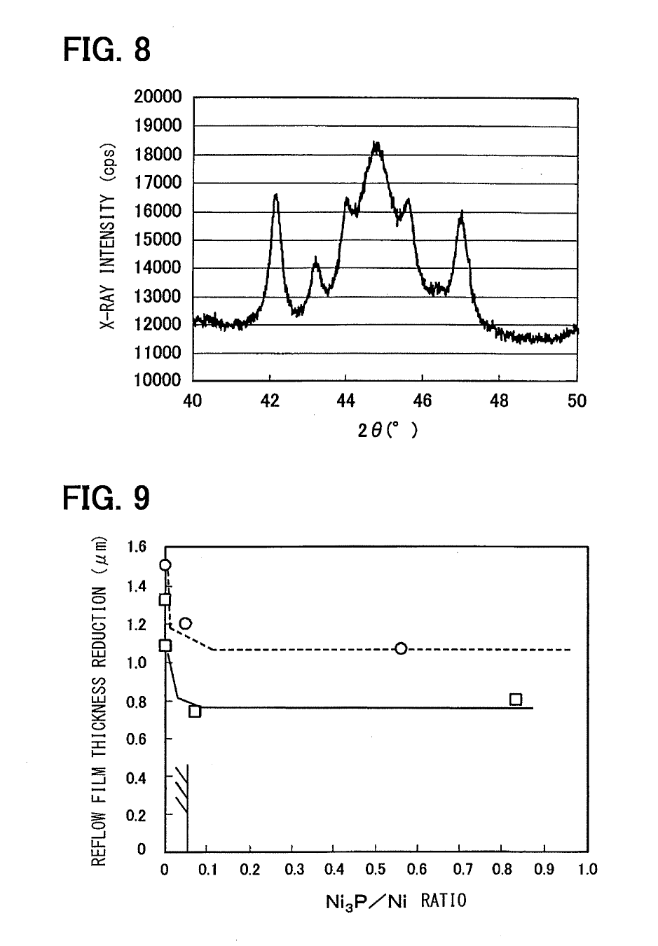

FIG. 8 shows an example of the X-ray diffraction measurement. As shown in FIG. 8, the X-ray diffraction of the metal film 20 containing Ni₃P has characteristic peaks. From peak ratios of the X-ray diffraction, the ratio Ni₃P/Ni capable of reducing the reduction in the thickness after reflow was investigated. FIG. 9 shows the result. FIG. 9 shows a relationship between the ratio Ni₃P/Ni and a reflow thickness reduction which is the amount of reduction in the thickness of the metal film 20 after the solder member 40 is joined.

According to FIG. 9, when the X-ray diffraction strength ratio Ni₃P/Ni is 0.05 or more, the effect of reducing the reduction in the film thickness can be obtained. In FIG. 9, a broken line represents a case where the metal film 20 is formed by plating, and a solid line represents a case where the metal film 20 formed by sputtering. In either case, the reduction in the film thickness is reduced when a lower limit on the ratio Ni₃P/Ni is set to 0.5 or more.

It is noted that an upper limit on the ratio Ni₃P/Ni is set to 2.0 or less based a Ni—P phase diagram. “Okamoto et al., “Binary Alloy Phase Diagrams second edition”, ASM International, 1990” is consulted for the Ni—P phase diagram.

Therefore, from the result of the X-ray diffraction measurement, when the ratio Ni₃P/Ni of the metal film 20 falls within a range of from 0.05 inclusive to 2.0 inclusive, the reduction in the thickness of the metal film 20 after the solder member 40 is joined can be reduced. Thus, the initial thickness of the metal film 20 can be smaller than that of the conventional metal film while the reliability of the metal film 20 with the small initial thickness is ensured.

### Second Embodiment

According to the present embodiment, the metal film 20 is manufactured by a method different from that of the first embodiment. Firstly, in a preparing process, a target used in sputtering is prepared. The target is formed by sintering Ni powders and Ni₃P powders.

Next, in a sputtering process, sputtering is performed using the target so that the metal film 20 including the Ni base 21 and the Ni₃P particles 22 can be formed on the semiconductor wafer or the semiconductor substrate 10. In the case of forming the metal film 20 on the semiconductor wafer, the semiconductor wafer is diced into individual semiconductor substrates. Thus, the semiconductor device having the metal film 20 is completed. The metal film 20 can be formed in this way.

### Third Embodiment

According to the present embodiment, the metal film 20 is manufactured by a method different from those of the first and second embodiments. The method of the present embodiment differs from the methods of the preceding embodiments in that the metal film 20 is formed by plating.

Firstly, in a preparing process, a plating solution containing Ni and P is prepared. Next, in a plating process, the semiconductor wafer or the semiconductor substrate 10 is soaked in the plating solution.

Then, in a heating process, the semiconductor wafer or the semiconductor substrate 10 is heated. Thus, the metal film 20 having the Ni base 21 and the Ni₃P particles 22 is formed on the semiconductor wafer or the semiconductor substrate 10. The metal film 20 can be formed in this way.

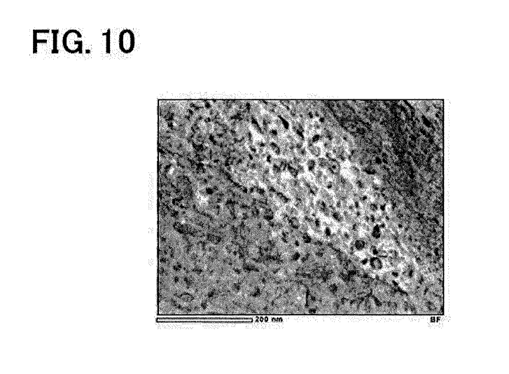

The present inventors investigated the metal film 20, which was formed by plating in the above manner, by TEM. FIG. 10 shows its TEM image. As can be seen from this drawing, particles are uniformly distributed. These particles are the Ni₃P particles 22. A size of the Ni₃P particle 22 is about 20 nm.

As described above, even when the metal film 20 is formed by plating, the metal film 20 containing the Ni₃P particles 22 can be formed by the above heating process.

### Fourth Embodiment

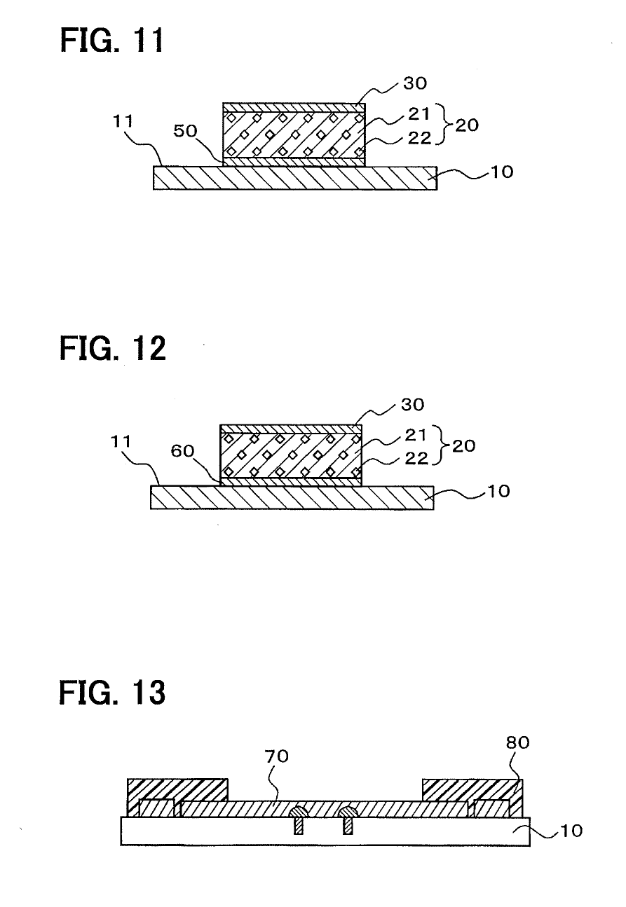

The present embodiment differs from the first to third embodiments in the following aspect. According to the present embodiment, as shown in FIG. 11, a metal film 50 is formed on the semiconductor substrate 10, and the metal film 20 is formed on the metal film 50.

The metal film 50 is made of Al or Cu. Since the metal film 50 made of Al or Cu is located between the semiconductor substrate 10 and the metal film 20 and in contact with the metal film 20, a contact resistance between the metal film 20 and the metal film 50 can be reduced.

### Fifth Embodiment

The present embodiment differs from the fourth embodiment in the following aspect. According to the present embodiment, as shown in FIG. 12, a metal film 60 is formed on the semiconductor substrate 10, and the metal film 20 is formed on the metal film 60.

The metal film 60 is made of Ti. Since the metal film 50 made of Ti is located between the semiconductor substrate 10 and the metal film 20 and in contact with the metal film 20, adhesion between the metal film 20 and the metal film 60 can be improved.

### Sixth Embodiment

FIG. 13 shows a case where a MOS structure as a semiconductor device is formed in the semiconductor substrate 10. Since the MOS structure is well known, its description is omitted. Regarding a structure on the semiconductor substrate 10, an Al film 70 for an electrode is formed on the MOS structure, and a polyimide film 80 for protection is formed abound the Al film 70.

In the case of FIG. 13, the metal film 20 according to the present disclosure is formed on the Al film 70. In FIG. 13, the metal film 20 on the Al film 70 is omitted. The solder member 40 is to be joined to the metal film 20 on the Al film 70. The metal film 20 can be used in this way.

### Seventh Embodiment

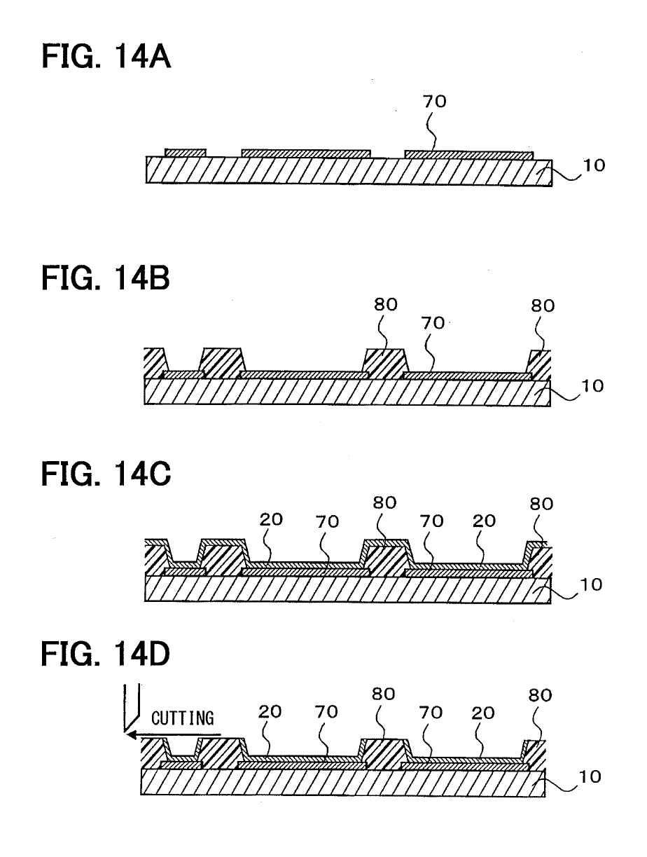

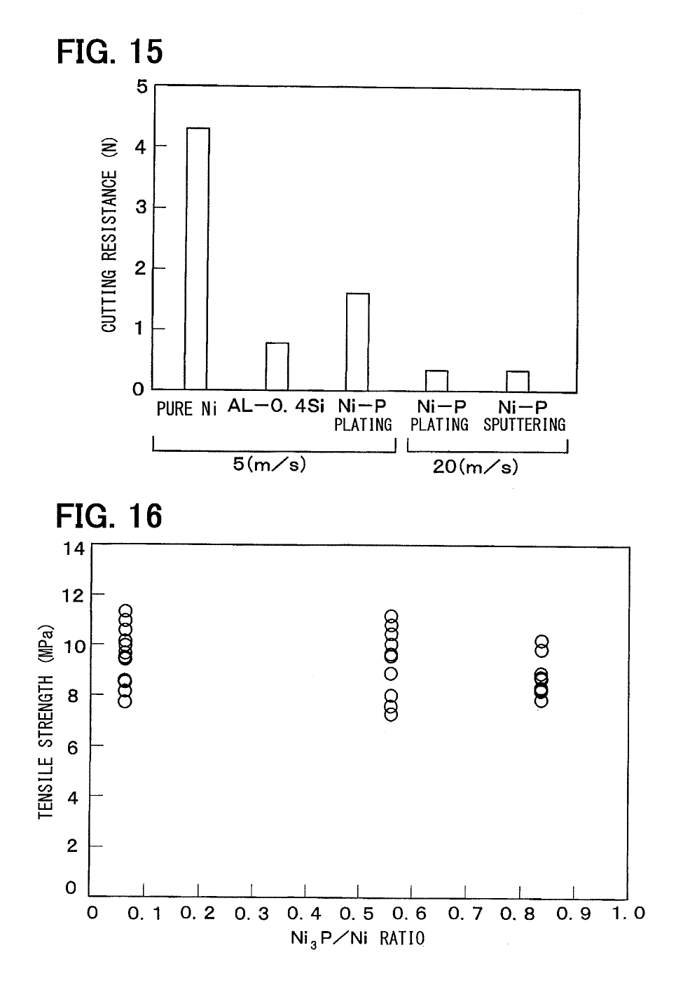

The present embodiment differs from the first to sixth embodiments in the following aspect. For example, as described in the sixth embodiment, when the metal film 20 is formed on the Al film 70, there is a need to cut an unnecessary portion of the metal film 20 after the metal film 20 is formed on the entire structure on the semiconductor substrate 10. A cutting process is described below with respect to FIGS. 14A-14D.

Firstly, the semiconductor wafer or the semiconductor substrate 10 where the semiconductor element is formed is prepared, and the Al film 70 is formed on the semiconductor wafer. Then, a photoresist is formed on the Al film 70, and lithography is performed so that openings can be formed at predetermined positions in the photoresist. Then, patterning of the Al film 70 is performed by etching the Al film 70 by using the photoresist as a mask. Then, the photoresist is so that a structure shown in FIG. 14A can be completed.

Then, the polyimide film 80 is formed to cover the Al film 70, and a photoresist is formed on the polyimide film 80. Then, the polyimide film 80 is patterned in a predetermined pattern in the same manner as described above, and patterning of the polyimide film 80 is performed by using the patterned photoresist as a mask. Then, the photoresist is so that a structure shown in FIG. 14B can be completed.

A structure shown in FIG. 14C can be obtained by forming the metal film 20 all over the structure shown in FIG. 14B. Then, the metal film 20 on the polyimide film 80 is removed by the cutting process. Thus, as shown in FIG. 14D, a structure where the metal film 20 is left on the Al film 70 can be obtained.

As described above, the metal film 20 according to the present disclosure can be processed by the cutting process. Since the Ni metal film 20 containing P has high abrasion resistance, and the reliability of the metal film 20 is high, the metal film 20 has an advantage against the cutting process. Further, since the Ni metal film 20 containing P is used, it is possible to reduce damages in the cutting process.

The present inventors tested the effectiveness of P (phosphorus) in the cutting process. Specifically, four films, including pure Ni, AL-0.4Si, Ni—P plating, and NiP sputtering, were formed, and a cutting resistance of each film was measured. FIG. 15 shows the result.

In FIG. 15, “pure Ni” represents a film purely made of Ni only, and “AL-0.4Si” represents an alloy film made of Al and 40 percent by weight of Si. “Ni—P plating” represents the metal film 20 formed by plating, and “Ni—P sputtering” represents the metal film 20 formed by sputtering. The pure Ni film, the AL-0.4Si film, and the Ni—P plating film were cut at a blade speed of 5 m/s. The Ni—P plating film and the NiP sputtering film were cut at the blade speed of 20 m/s.

Regarding the cutting resistance of each film, the cutting resistance is smaller when the blade speed is 20 m/s than when the blade speed is 5 m/s. In particular, the cutting resistance of the Ni—P plating metal film 20 decreases as the blade speed increases from 5 m/s to 20 m/s. The cutting resistance of the Ni—P sputtering metal film 20 is smaller than those of other films due to the fact that the blade speed is 20 m/s.

From a macro point of view, it can be considered that a reason for the decrease in the cutting resistance is that P expresses a self-lubricating property in iron-based materials containing Ni in a temperature range of 300° C. to 800° C. In contrast, from a micro point of view, it can be considered that the reason is that the metal film 20 containing the Ni₃P particles 22 changes to a material which is likely to be dissolved chemically. Further, since the melting temperature 870° C. of Ni₃P is lower than a melting temperature 1455° C. of pure Ni, the metal film 20 becomes liquid and likely to be deformed by heat in the cutting process.

As described above, when the metal film 20 containing Ni₃P is processed in the cutting process, the cutting resistance decreases. Therefore, the metal film 20 can be cut by a small amount of force. Further, since a temperature of an edge of the blade increases with the blade speed in the cutting process, the cutting resistance further decreases. Accordingly, a life of the blade used in the cutting process can be increased. Further, a cost of the blade, as a consumable, used in the cutting process can be reduced. Furthermore, a cost of labor necessary to replace the blade used in the cutting process can be reduced.

### Eighth Embodiment

The present embodiment differs from the first to seventh embodiments in the following aspect. According to the above embodiments, the ratio of the Ni base 21 to the Ni₃P particles 22, i.e., the X-ray diffraction strength ratio Ni₃P/Ni is defined as being within the range of from 0.05 inclusive to 2.0 inclusive. According to the present embodiment, the present inventors examined the optimum value of the ratio Ni₃P/Ni in depth.

Specifically, a sample in which a standard wire of copper was joined through solder on the metal film 20 formed by plating was prepared, and the optimum value of the ratio Ni₃P/Ni was investigated by measuring a tensile strength of the standard wire. FIG. 16 shows the result. It is noted that the ratio Ni₃P/Ni as the horizontal axis of FIG. 16 was determined from X-ray diffraction peak ratios in the same manner as in the first embodiment.

As shown in FIG. 16, when the X-ray diffraction strength ratio Ni₃P/Ni is 0.05 or more, the tensile strength of 6 MPa or more higher than that of the semiconductor substrate 10 made of Si can be obtained. Therefore, according to the present embodiment, it can be said that the lower limit on the ratio Ni₃P/Ni is 0.05.

In contrast, the maximum value of the ratio Ni₃P/Ni necessary to obtain the tensile strength of 6 MPa or more is 0.83. In other words, at least when the ratio Ni₃P/Ni is 0.83 or less, the metal film 20 can have high strength. For this reason, the film strength of the metal film 20 can be ensured by setting the upper limit on the ratio Ni₃P/Ni to 0.83.

As described above, based on the measurement result of the tensile strength against the metal film 20, the ratio of the Ni base 21 to the Ni₃P particles 22, i.e., the X-ray diffraction strength ratio Ni₃P/Ni can be defined as being within a range of from 0.05 inclusive to 0.83 inclusive. Regarding the tensile strength against the metal film 20 formed by sputtering, the result indicates that it is optimum that the X-ray diffraction strength ratio Ni₃P/Ni be defined as being within the range of from 0.05 inclusive to 0.83 inclusive.

### Ninth Embodiment

The present embodiment differs from the first to eighth embodiments in the following aspect. According to the present embodiment, a stoichiometric compound NiₓP_{y}, where each of x and y is an integer, is employed as a material having condensation energy higher than that of Ni. That is, the metal film 20 includes the Ni base 21 and a NiₓP_{y} intermetallic compound mixed with the Ni base 21.

A composition of NiₓP_{y} depends on x and y. For example, when x=3 and y=1, the stoichiometric compound becomes Ni₃P. That is, Ni₃P is one example of the composition of NiₓP_{y}. As described above, any material satisfying the composition of NiₓP_{y} including the Ni₃P can be employed

### Tenth Embodiment

The present embodiment differs from the first to ninth embodiments in the following aspect. The material bonding to Ni is not limited to P (phosphorus) which has condensation energy higher than that of Ni, but can be another material.

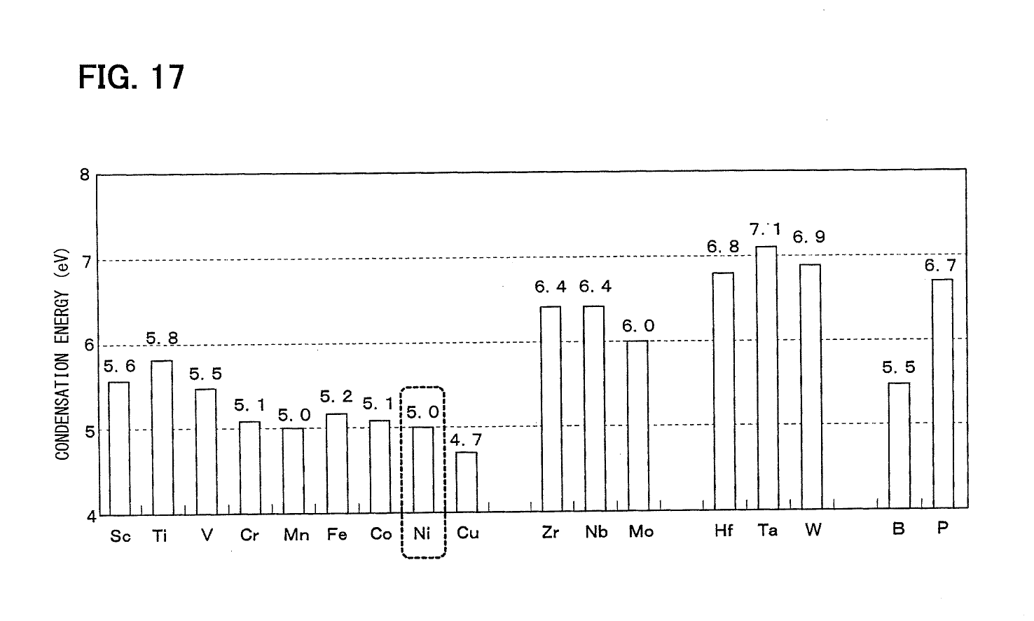

Specifically, as shown in FIG. 17, the other material can be any one of Sc (scandium), Ti (titanium), V (vanadium), Cr (vanadium), Fe (iron), Co (cobalt), Zr (zirconium), Nb (niobium), Mo (molybdenum), Hf (hafnium), Ta (tantalum), W (tungsten), and B (boron). As described above, in addition to P, there are materials which are capable of bonding to Ni and have condensation energy higher than that of Ni. In particular, Zr, Nb, Mo, Hf, Ta, W, B, and P have very high effect on stabilizing an alloy when being added to Ni.

As described above, there are a variety of materials bonding to Ni. Therefore, when M is defined as a material having high condensation energy, Ni-M becomes an alloy or a compound according to a material bonding to Ni.

As described above, the metal film 20 can have the Ni base 21 and a material having high condensation energy than that of Ni. As the condensation energy of the material is higher, the stability of the metal film 20 becomes higher. Further, the metal film 20 can have high film density.

### Other Embodiments

While the present disclosure has been described with reference to embodiments thereof, it is to be understood that the disclosure is not limited to the embodiments. The present disclosure is intended to cover various modifications and equivalent arrangements within the spirit and scope of the present disclosure.

For example, since what is needed is that the Ni base 21 contains the Ni₃P particles 22, it is not always necessary that the Ni₃P particles 22 are uniformly distributed in the Ni base 21. Unsurprisingly, since the mechanical strength decreases when the Ni3P particles 22 adhere to each other in the form of a layer, it is preferable that the Ni3P particles 22 be distributed.

Although the first embodiment describes the structure where the Au thin-film 30 is formed on the metal film 20, this is an example of a structure of the semiconductor device. Therefore, it is not always necessary that the Au thin-film 30 is formed on the metal film 20. In this case, the solder member 40 containing Sn is directly joined on the metal film 20. Alternatively, in the fourth and fifth embodiments, the Au thin-film 30 can be formed on the metal film 20. Instead of the Au thin-film 30, an Ag thin-film (not shown) can be formed on the metal film 20. Thus, the Au thin-film 30 or the Ag thin-film can be used as an antioxidant film.

The semiconductor device can be used in a vehicle, for example, as a device for an in-vehicle power source or as a device for driving a vehicle motor. In these usage environments, an optimum value of the film thickness of the metal film 20 for a vehicle is 2.6 μm.

The metal film 20 according to the present disclosure is suitable for an electrode material of a double sided heat dispersion structure subjected to stress, because a reduction in the film thickness is reduced by the solder member 40.

1. A semiconductor device comprising:
a semiconductor substrate; and
a metal film formed on the semiconductor substrate, wherein
the metal film includes a Ni base and a material having condensation energy higher than that of Ni.

2. The semiconductor device according to claim 1, wherein
the material having condensation energy higher than that of Ni is any of Sc, Ti, V, Cr, Fe, Co, Zr, Nb, Mo, Hf, Ta, W, B, and P.

3. The semiconductor device according to claim 1, wherein
the material having condensation energy higher than that of Ni is a stoichiometric material represented by NiₓP_{y}, where each of x and y is an integer.

4. The semiconductor device according to claim 1, wherein
the material having condensation energy higher than that of Ni is a Ni₃P particle.

5. The semiconductor device according to claim 4, wherein
the Ni₃P particle is uniformly distributed in the Ni base.

6. The semiconductor device according to claim 1, further comprising:
another metal film made of Al or Cu and located between the semiconductor substrate and the metal film, the other metal film being in contact with the metal film.

7. The semiconductor device according to claim 1, further comprising:
another metal film made of Ti and located between the semiconductor substrate and the metal film, the other metal film being in contact with the metal film.

8. The semiconductor device according to claim 1, further comprising:
a solder member containing Sn and joined to a top surface of the metal film.

9. The semiconductor device according to claim 4, wherein
a ratio of the Ni base to the Ni₃P particle is defined as Ni₃P/Ni, and
the ratio Ni₃P/Ni ranges from 0.05 inclusive to 2.0 inclusive.

10. The semiconductor device according to claim 9, wherein
the ratio Ni₃P/Ni ranges from 0.05 inclusive to 0.83 inclusive.

11. The semiconductor device according to claim 4, wherein
a ratio of a X-ray diffraction strength of the Ni base to a X-ray diffraction strength of the Ni₃P particle is defined as Ni₃P/Ni, and
the ratio Ni₃P/Ni ranges from 0.05 inclusive to 2.0 inclusive.

12. The semiconductor device according to claim 11, wherein
the ratio Ni₃P/Ni ranges from 0.05 inclusive to 0.83 inclusive.

13. A method of manufacturing a semiconductor device comprising:
a step of preparing a semiconductor substrate and a target which is formed by melting P in Ni, and
a step of forming a metal film having a Ni base containing a Ni₃P particle on the semiconductor substrate by sputtering with the target while heating a portion of the semiconductor substrate where the metal film is to be formed to a temperature of from 280° C. inclusive to 870° C. inclusive.

14. A method of manufacturing a semiconductor device comprising:
a step of preparing a semiconductor substrate and a target which is formed by sintering Ni powder and Ni₃P powder, and
a step of forming a metal film having a Ni base containing a Ni₃P particle on the semiconductor substrate by sputtering with the target.

15. A method of manufacturing a semiconductor device comprising:
a step of preparing a semiconductor substrate and a plating solution containing Ni and P;
a step of soaking the semiconductor substrate in the plating solution, and
a step of forming a metal film having a Ni base containing a Ni₃P particle on the semiconductor substrate by heating the semiconductor substrate after the soaking step.
